(19) United States
(12) Patent Application Publication
(10) Pub. No.: US 2007/0150784 A1
(43) Pub. Date: Jun. 28, 2007

(54) Method and system for data and video coding

(75) Inventors: Chia-Ho Pan, Tainan County (TW); I-Hsien Lee, Hsinchu City (TW); Liang-Gee Chen, Taipei County (TW)

Correspondence Address: AKIN GUMP STRAUSS HAUER & FELD L.L.P., ONE COMMERCE SQUARE, 2005 MARKET STREET, SUITE 2200, PHILADELPHIA, PA, 19103, US

(73) Assignee: Industrial Technology Research Institute

(21) Appl. No.: 11/361,578

(22) Filed: Feb. 24, 2006

(30) Foreign Application Priority Data
Dec. 12, 2005 (CN) 200510130537.0

(51) Int. Cl. H04L 1/00; H03M 13/00; G08C 25/00; G06F 11/00; G06F 11/30

(52) U.S. Cl. 714/746

(57) ABSTRACT

The invention provides a video coding method. The method may include: receiving a set of video data for transmission; identifying at least two partitions from the video data, a first partition containing at least a portion of decoding information enabling a decoding of the video data, and a second partition containing at least a portion of information indicative of video content; encoding at least a portion of the first partition at an application layer of a system to generate partition protection information, the partition protection information allowing a recovery of first partition data when an error occurs to the first partition data; and transmitting the first partition, the partition protection information, and the second partition.

### BACKGROUND OF THE INVENTION

1. Field of the Invention

The present invention generally relates to data and video coding. More particularly, the present invention may be applied as an error correction scheme for protecting data or video information or its header information, such as by applying the error correction scheme at the application layer of data or video coding.

2. Background of the Invention

Multimedia communication, such as the exchange of audio and video data, plays an important role in our daily life. This exchange can take place over wired or wireless networks or mediums. For example, a real-time video service may provide on-the-fly video data over one or more wireless networks. However, certain transmission options, especially wireless ones, may challenge accurate or adequate data transmission due to data loss, signal noise, or signal interference caused by various factors, such as fading channel and multi-path effects. For example, a “noisy” channel may corrupt transmitted data and causes unpredictable errors in the transmitted data.

Certain mechanisms have been proposed to improve the accuracy of transmitted data or to reduce noise effects and other undesirable interferences. For example, Forward Error Correction (“FEC”) scheme introduces redundant bits into the to-be-transmitted data at the transmitting end to allow a decoder at the receiving end use the redundant bits to correct the errors occurred during transmission. The error-correcting ability of FEC may depend on the amount of redundancy embedded in a system. As a result, the error-correcting ability may depend on the bit-rate available for data transmission and channel interference may still significantly impact the transmitted data.

Multimedia communication involving compressed video bitstream may be very sensitive to errors, as any loss of information may impact the reconstructed or decoded video data. Currently, known error-resilience methods use different approaches to reduce transmission errors. For example, some methods focus on using spatial or temporal redundancy to reduce errors that corrupt macroblocks (MBs). Other methods provide data protection for header information of coded bitstreams, such as an HEC (Header Extension Code) technique that duplicates certain header information at slice or packet levels. And certain techniques, including Unequal Error Protection (UEP) techniques, may provide separate levels of protection for separate sections of data to ensure that data can be adequately decoded for providing video information of acceptable quality. For example, a more reliable sub-channel, a stronger FEC code, or more frequent retransmission, may be provided. However, existing networks, transmission protocols, and transmission systems may not support UEP or certain error-reduction techniques. Therefore, those techniques may have a lower application value or may significantly increase the application costs.

Given certain limitations of existing methods or systems, there is a need for improved data or video coding methods and systems that protect the data or video or reduce the effect of transmission errors.

### SUMMARY OF THE INVENTION

Examples consistent with the invention may provide a video coding method. The method may include: receiving a set of video data for transmission; identifying at least two partitions from the video data, a first partition containing at least a portion of decoding information enabling a decoding of the video data, and a second partition containing at least a portion of information indicative of video content; encoding at least a portion of the first partition at an application layer of a system to generate partition protection information, the partition protection information allowing a recovery of first partition data when an error occurs to the first partition data; and transmitting the first partition, the partition protection information, and the second partition.

Examples consistent with the invention may also provide a system capable of performing video coding. The system may include: an input interface for receiving a set of video data for transmission; a data processing device for identifying at least two partitions from the video data, a first partition containing at least a portion of decoding information enabling a decoding of the video data, and a second partition containing at least a portion of information indicative of video content; an encoding device being capable of encoding at least a portion of the first partition at an application layer of the system to generate partition protection information, the partition protection information allowing a recovery of first partition data when an error occurs to the first partition data; and a transmission interface for transmitting the first partition, the partition protection information, and the second partition.

Examples consistent with the invention may also provide a computing system comprising a memory to store instructions and a processor configured to process the instructions. In particular, the processor processes the instructions to perform steps including: receiving a set of data for transmission; identifying at least two partitions from the data, a first partition containing at least a portion of decoding information enabling a decoding of the data, and a second partition containing at least a portion of information indicative of data content; encoding at least a portion of the first partition at an application layer of the system to generate partition protection information, the partition protection information allowing a recovery of first partition data when an error occurs to the first partition data; and transmitting the first partition, the partition protection information, and the second partition.

These and other elements of the invention will be more fully understood upon reading the following detailed description in conjunction with the accompanying drawings.

### BRIEF DESCRIPTION OF THE SEVERAL VIEWS OF THE DRAWINGS

The foregoing summary, as well as the following detailed description of examples of the invention, will be better understood when read in conjunction with the appended drawings. For the purpose of illustrating the invention, the drawings provide illustrative examples. It should be understood, however, that the invention is not limited to the precise arrangements and instrumentalities shown. In the drawings:

FIG. 1 illustrates an example of applying data partition and unequal error protection for separate partitions.

FIG. 2a illustrates an exemplary flow chart of one example consistent with the invention.

FIG. 2b illustrates an example of applying error correction coding at an application layer in examples consistent with the invention.

FIG. 3 illustrates an example of separate code rates of channel coding needed to satisfy separated levels of BER in examples consistent with the invention.

FIG. 4 illustrates an example of the variation of frame-by-frame luminance PSNR values over time of a decoded exemplar sequence in examples consistent with the invention.

FIG. 5 is an exemplary diagram plotting average PSNR values over bit-rates at which video bitstreams are decoded in examples consistent with the invention.

### DESCRIPTION OF EMBODIMENTS

Reference will now be made to embodiments of the invention, examples of which are illustrated in the accompanying drawings.

Examples consistent with the invention provide methods and systems for coding data, such as coding video data, which can address undesirable channel effects or the corruption of received data over wired or wireless networks. In one example, an error correction or data protection technique may be applied at an application layer of a system, e.g., application program running on a computing system, a wireless video system, or a video transmission system. In some examples, the techniques at the application layer can be implemented without modifying the standard protocols or syntax for transmitting multimedia or video data or bitstream. For example, a coded bit stream at the application layer containing video or other information may be transmitted over a wireless network and provide acceptable or adequate data for reconstructing the information or recovering error-affected information at a receiving system. In some examples, an error correction code may be applied to protect the header information of a section of video, audio, or multimedia information. As an example, the error correction code can be embedded into the original data stream containing video, audio, or multimedia data by placing it in a separate section, such as the “user_defined_data” field offered under the MPEG-4 (Motion Picture Expert Group, Version 4) standard, or by using data hiding techniques. In some example, applying the error correction coding at an application layer can avoid the need for a complex system in protecting the data to be transmitted.

Multimedia data, including video, audio, or other information for transmission, may be coded in various ways to compress the data or provide adequate accuracy for transmission. As an example, video coding may use a Variable Length Code (“VLC”) scheme to compress video information. However, if a transmission error corrupts a VLC symbol in a compressed video bitstream, a decoder at a receiving system may not be able to identify the correct symbol. And the data following the unidentifiable symbol may also become unusable due to the inter-dependency among a group of VLC symbols. In some examples, if an error occurs in the header of a bitstream or a section that is instructive in decoding a group of data, the impact may be as significant as precluding the decoding of the entire bitstream relating to that header or section.

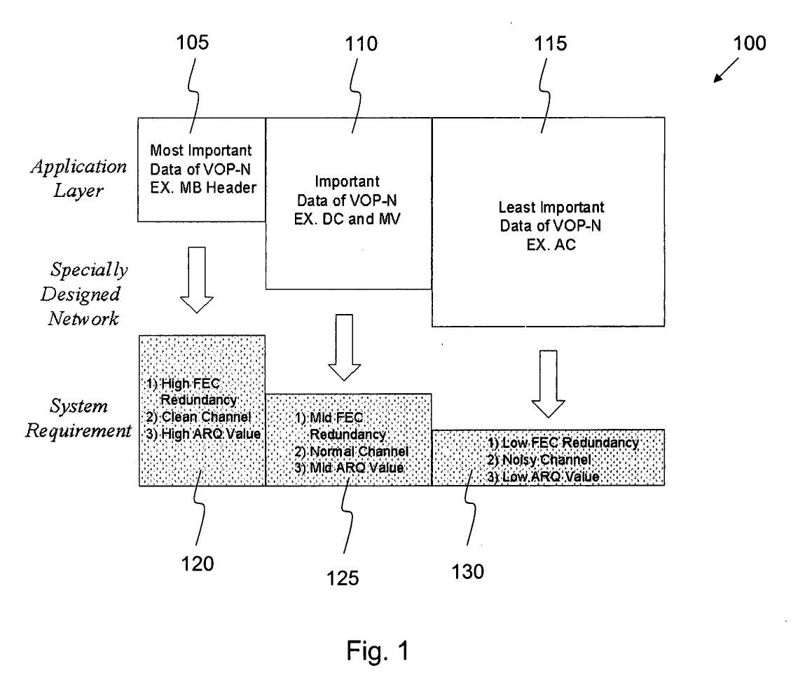

In some examples, video coding may emphasize error-reduction for the header information or certain section of a bitstream that may be necessary for reconstructing the transmitted data. For example, data partition can be applied to split a video bitstream into two or more partitions, such as having two partitions of a first partition containing coding mode information for each macroblock together with DC coefficients of INTRA block or motion vectors for INTER blocks and a second partition containing the remaining data. As an example, more efforts may be applied for protecting the information necessary to decode video frames. FIG. 1 illustrates an example of applying data partition and unequal error protection for separate partitions. Referring to FIG. 1, three levels of importance, such as levels 105, 110, and 115 illustrated at an application layer, may be assigned to separate types of data in one or more video bitstreams for transmission, and separate levels of FEC redundancy, separate channels, separate ARQ (Automatic Retransmission Requests) values, or a combination of those, may be respectively applied for those separate types of data. For example, blocks 120, 125, and 130 illustrate examples of applying different levels of protection, or different levels of system requirements, at a transmission interface or system level for protecting data having different levels of importance.

However, depending on how the technique is implemented, certain implementations may require significant changes in existing systems, transmission protocols, or bit rates required. For example, as illustrated in FIG. 1, a specially designed network may be needed for implementing the method. And the effectiveness of some implementations may depend on the availability of up-to-date channel information. In some examples, a small amount of redundant or data-protection information may be incorporated as a part of the original information for transmission, and system providers may treat the protected data as a part of ordinary bitstream. But a receiving system recognizing the protected data may be able to use such information to correct or recover certain information, such as video header information or other portions of transmitted data.

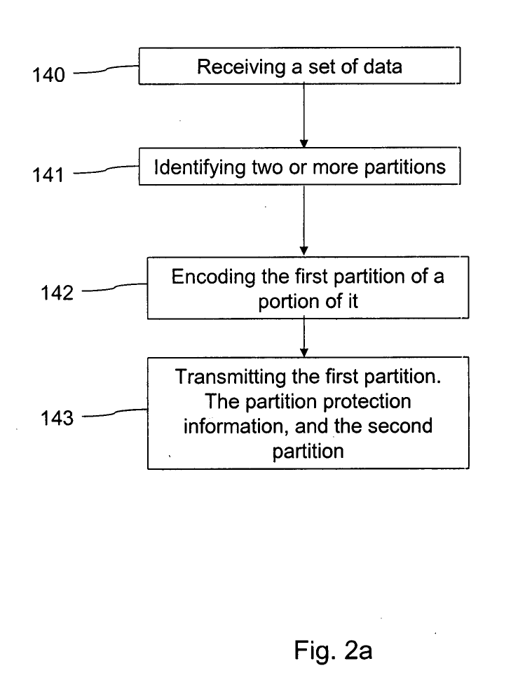

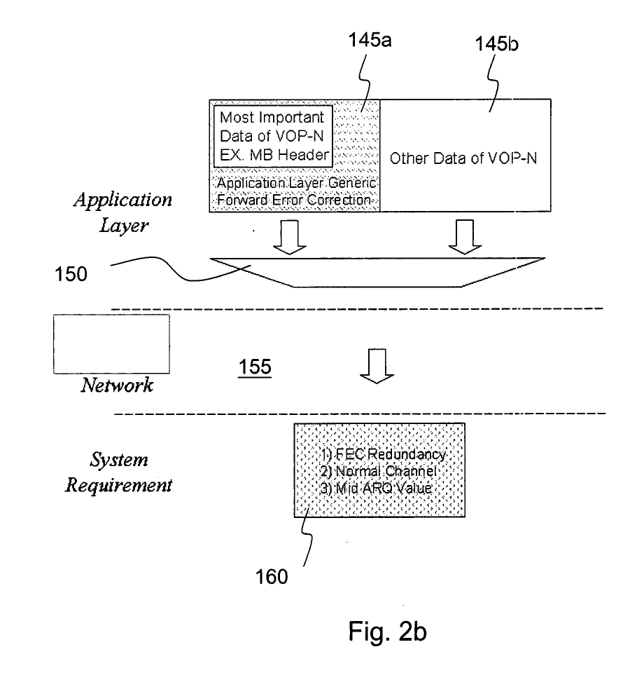

Examples of the invention may include methods of protecting or coding video, audio, multimedia, or other data. FIG. 2a illustrates an exemplary flow chart of one example of the method. For example, referring to FIG. 2a, a method may include, at step 140, receiving a set of data, such as a set of video data or coded video data for transmission or a video stream. Two or more partitions may be identified from the data or video data at step 142. For example, a first partition may contain at least a portion of decoding information that enables the decoding of the data, such as video or other coded data. In the case of a video stream, the first partition may contain the header of a video stream or a portion of the header. A second partition may contain the content of the data itself, such as information indicative of video content or at least a portion of such information.

To protect the first partition, the first partition or at least a portion of it may be encoded at an application layer of a system, at step 142, to generate partition protection information, which may allow the recovery of first partition data when an error occurs to the first partition data. For example, if some errors occur to the header of a video stream, the partition protection information may allow the recovery or reconfiguration of some of all of the error-affected header information. The first partition, the partition protection information, and the second partition may then, at step 43, be transmitted, such as transmitted over a wired or wireless network to one or more data receiving systems. In one example, the first partition, the partition protection information, and the second partition may be combined as one protected bitstream, which may maintain the syntax of the original video or data.

In some examples, the operations of identifying two or more partitions and encoding at least a portion of the first partition may occur at an application layer of a video data transmission system. Such application may avoid the need to modify transmission standards or protocols and simplify the design of video systems. In another example, these operations may occur before video data reaches a media access control (MAC) layer of a video data transmission system. Additionally, the first partition, the partition protection information, and the second partition may be transmitted in the syntax of, or in a syntax similar to that of, the original data, such as the syntax of the original video data. Such technique may allow a receiving system that does not support or recognize the coding mechanism illustrated above to still be able to receive and decode the transmitted data.

The encoding of a portion of the first partition coding may be conducted in various ways. For example, the encoding may involve an application-layer error correction coding to generate an application-layer error correction code as the partition protection information. In an example with video data, the encoding may include generating an error correction code for the header information of the video data. In some examples, the encoding may include applying Hamming Code as an error correction code. In an example of coding a video bitstream, the first partition, the partition protection information, and the second partition may be transmitted in one video bitstream.

Accordingly, in some examples, critical information of a video bitstream, such as header information, may be placed in a separate partition and an error correction code may be applied to protect such information or a portion of it. In some examples, conducting such process at an application layer of a system may avoid the need for a complicated system. After the error correction coding, the partition protection information, or the redundancy generated as the result of the error correction coding, may be transmitted in combination with video information or as ordinary video information. FIG. 2b illustrates an example of applying error correction coding at an application layer. Referring to FIG. 2b, important data, such as the data of VOP-N (Video Object Plane-N) or the header of video macroblock (MB) may be protected with forward error correction (“FEC”) coding. And the method may use only a single transport and physical channel without requiring additional channels or requiring a channel of optimum quality of transmission. In some examples, such technique may reduce or avoid the need to adjust factors such as the FEC coding mode, the transmission power, or the number of ARQs (Automatic Retransmit Requests) to increase the correction probability of important information.

In some examples, the first partition 145a may include only the video header information or a portion of it. Therefore, the additional partition protection information generated as a result of the encoding process is limited. In one example of using Hamming Code as the error correction method in an application layer, only an additional bit-rate of 1 kbps is required for a typical video stream. And, in some examples, the encoding operation does not change or impact the original header information, due to the characteristics of Hamming Code. In various examples, the partition protection information may be easily incorporated into the original bitstream without having to modify the syntax of existing standards, including video codecs under standards such as MPEG-4 (Motion Picture Expert Group, Version 4).

In some examples, the partition protection information, a small amount of redundancy, may be included in the bitstream using digital watermarking or data-hiding techniques.

Also, the partition protection information may be placed in certain field or section of a video stream, such as the “user_defined_data” or other field offered under the MPEG-4 standard. In some examples, because encoding the first partition or a portion of it, such as by Hamming Code, does not affect the first partition or the header information itself, the partition protection information may be included in the video data or video bitstream following its original syntax. In some examples, the partition protection information may be included as a part of the second partition 145b or video content, including as certain data replacing the less or least important bits of the video data. In some other examples, the partition protection information may be appended to the end of the second partition 145b or video data. In examples where the original syntax or a similar syntax is followed, a decoder not supporting the proposed error correction technique, such as an application-layer error correction, can still decode a coded bitstream. As noted above, blocks 145a and 145b, which may include the first partition, the partition protection information, and the second partition, may be combined or encoded as one protected bitstream at application 150. A common or ordinary network without customized design may be used for transmitting the bitstream. And the system requirement at a transmission interface or system level with average or ordinary protection as illustrated in block 160 may be applied.

Exemplary simulations have been performed using the methods illustrated above. In some examples, although applying the encoding operation may slightly increase the amount of data by a certain percentage, such as by about 1% or less, the transmission rate can be significantly reduced, especially in wireless applications, because less redundancy or protection is needed for the transmission. For example, from a system point of view, the information of application layer may be further protected by using FEC coding or other coding before actual transmission takes place. As an example, the level of FEC redundancy or code rate of channel coding to provide acceptable video data after the transmission may depend on the Bit Error Rate (“BER”) that a video decoder can tolerate. A looser BER requirement may result in reduced level of redundancy needed for channel coding. Because certain data in a set of video data received is protected by the partition protection information, a loosened BER requirement, the reduction in the code rate of channel coding, or both, may become possible.

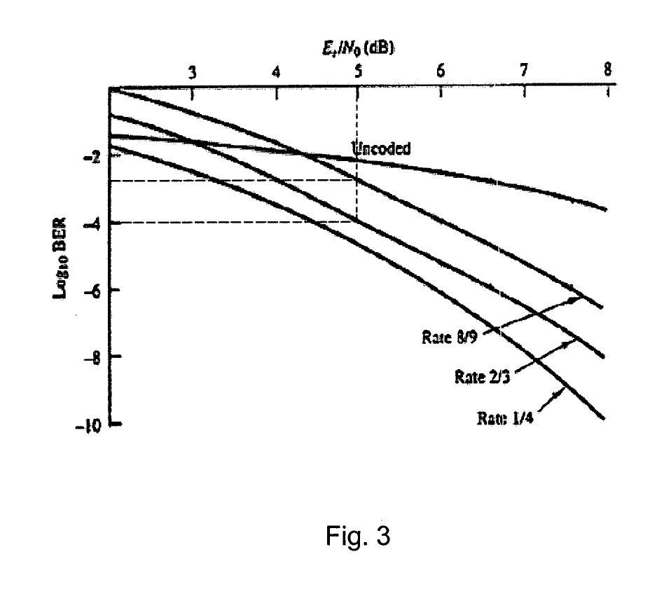

For example, for a video decoder operated at a BER of 10⁻³, a relatively loose BER in providing real-time video, header information often becomes corrupted, which leads to seriously degraded picture quality at a receiving system. And a BER of 10⁻⁴ is often needed to provide an acceptable picture quality after a video bitstream is transmitted. In contrast, applying the techniques illustrated above may offer improved recovery for important information such as the header information used in a video decoding procedure. FIG. 3 illustrates an example of separate code rates of channel coding needed to satisfy separated levels of BER. Referring to FIG. 3, three curves corresponding to three separate code rate are illustrated. For a noise ratio of about 5 dB, only a code rate of 8/9, or a 12.5% redundancy rate, is be needed to satisfy a BER of 10⁻³. And only a code rate of 2/3, or 50% redundancy rate, is needed to satisfy a BER of 10⁻⁴. In some examples, the proposed method may save total transmission bit rate needed or the level of redundant bits needed for providing adequate data transmission.

Exemplary simulations were also conducted under two exemplary scenarios that may occur in providing a real-time video service. The first scenario may occur in broadcasting services, where a channel code encoder or video encoder may not have feedback from one or more receiving systems to adapt its coding process. Accordingly, errors may propagate over time until the video decoder at a receiving system receives a new INTRA block. The second scenario considers a feedback channel for a real-time video service. For example, a channel code encoder or video encoder may be notified when the transmission of some data or a picture fails due to the corruption of errors in certain information, such as in picture header. Accordingly, a channel code encoder or a video encoder may use such notifications as feedback information and attempt to reduce or stop error propagation.

In one example, Hamming Code may be used as an error correction code to protect certain information of a set of data, such as the header information of an H.264 video bitstream. The header information may include a sequence layer header, a picture layer header, and a slice layer header. In one example, the amount of redundant bits to protect these headers is about 1 kbps. Errors may be generated by applying random noises at a BER of 10⁻³ to corrupt two exemplary bitstreams, one with header protection and another without header protection. Some criteria may be set for the exemplary simulations. For example, a corrupted frame may be replaced by copying the information from the nearest frame, and the header information in the first frame is free of errors. Several video sequences may be used for testing the system performance. Each sequence may contain a number of frames, such as 300 frames and may be coded as I-P-P-P-P-P . . . , which means that the first frame is intra-coded and all other frames are inter-coded. Table 1 below illustrates the peak signal-to-noise ratio (“PSNR”) with/without header protection at a quality value of QP (Quantization Parameter)=28 under scenario 1 described above.

| Sequence | PSNR(Y) | PSNR(U) | PSNR(V) |
|---|---|---|---|
| S1 | 36.11/27.72 | 40.18/38.44 | 40.98/38.88 |
| S2 | 33.51/28.83 | 34.68/33.70 | 34.39/33.43 |
| S3 | 37.41/35.55 | 41.38/41.27 | 42.16/41.99 |

As an example, the PSNR values of decoding the video bitstreams may be obtained by using H.264 reference software JM9.6. As illustrated by Table 1, the various PSNR values for various sequences with header protection usually are higher than those values for various sequences without header protection.

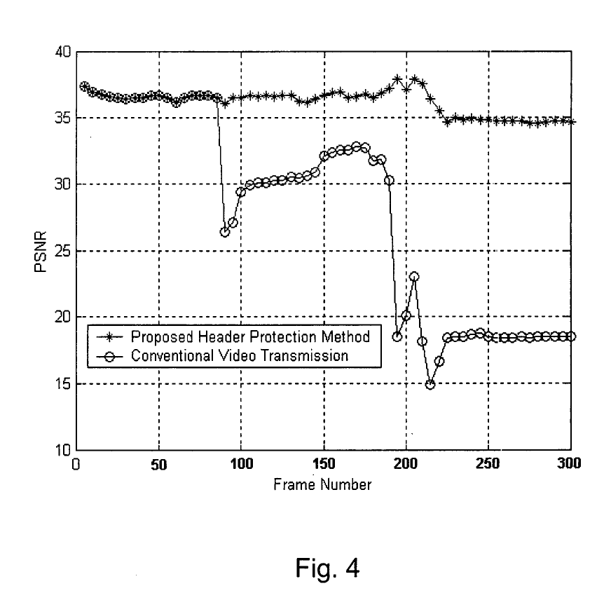

Generally, using neighboring frame information after having a corrupted header will seriously corrupt reconstructed picture in a fast-moving sequence because two neighboring frames may be very different, Although some INTRA blocks in the frames following an initial frame may allow the recovery of corrupted pictures to slightly improve PSNR performance, these INTRA blocks still cannot compensate for the errors in a corrupted header. And the errors tend to propagate to all those following frames and further degrade PSNR performance. FIG. 4 illustrates an example of the variation of frame-by-frame luminance PSNR values over time of a decoded exemplar sequence. Referring to FIG. 4, the decoding of a sequence without header protection may have its PSNR performance degrade significantly over time, while the decoding of a sequence with header protection may provide stable and acceptable PSNR performance.

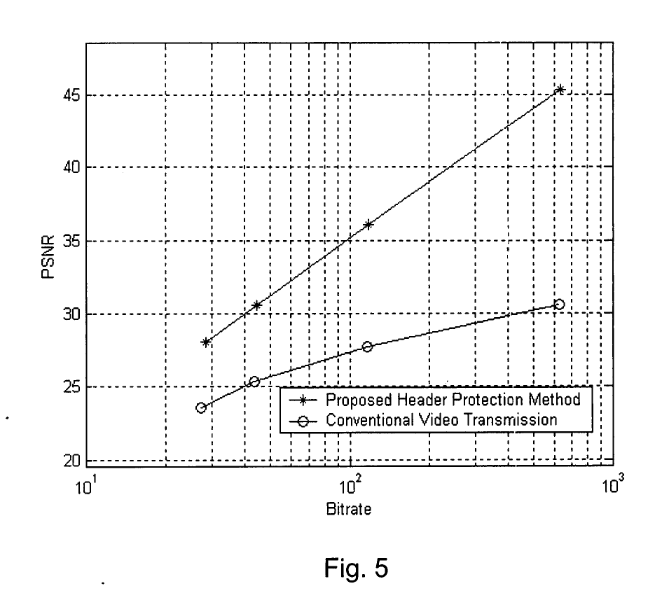

FIG. 5 is an exemplary diagram plotting average PSNR values over bit-rates at which video bitstreams are decoded in one example. Referring to FIG. 5, the protected stream may outperform the unprotected stream by 5 dB or more.

For a system that has feedback, the feedback channel can inform a video decoder that certain information has been corrupted and should not be used as reference information. One may assume that the latency in providing such information to the decoder may take a time interval of two frames. Accordingly, any frames thereafter may be able to have a proper reference and the error propagation may cease. Table 2 below illustrates the peak signal-noise ratio (PSNR) with/without header protection at a quality value of QP (Quantization Parameter)=28 under scenario 2. As illustrated by Table 2, the various PSNR values for various sequences with header protection usually are higher than those values for various sequences without header protection.

| Sequence | PSNR(Y) | PSNR(U) | PSNR(V) |
|---|---|---|---|
| S1 | 36.11/35.77 | 40.18/40.03 | 40.98/40.85 |
| S2 | 33.51/33.32 | 34.68/34.64 | 34.39/34.34 |
| S3 | 37.41/37.35 | 41.38/41.40 | 42.16/42.16 |

In some examples, a system capable of performing data coding or video coding may be provided to implement the methods illustrated above. For example, the system may include an input interface for receiving a set of video data for transmission. The system may also include a data processing device for identifying at least two partitions from the video data. In particular a first partition may contain at least a portion of decoding information that enables a decoding of the video data, and a second partition may contain at least a portion of information indicative of video content. The system also may include an encoding device that is capable of encoding at least a portion of the first partition to generate partition protection information. The partition protection information allows a recovery of first partition data when an error occurs to the first partition data. Additionally, the system may include a transmission interface for transmitting the first partition, the partition protection information, and the second partition.

Various types of systems may be used to implement the methods illustrated above. For example, the system may be a computer, a processor at a multimedia transmission or video transmission system, a dedicated hardware, a processor executing a set of firmware or software instructions; a combination of logics, etc.

As illustrated above, methods for coding data, such as video data, may provide protection for at least a portion of decoding information that enables a decoding of the data, such as the header of a video bitstream. An error correction coding may be applied at an application layer in one example. In an error-prone channel, the methods may avoid or reduce header information errors to allow improved video decoding in some examples. In some examples, the methods may avoid the need to modify the syntax of existing standards, and the redundant bits can be concealed in the bitstream with various techniques. Such implementation may provide compatibilities with existing standard. Additionally, examples of the methods may be applied in any communication networks or transmission environments.

The foregoing disclosure of the examples of the invention has been presented for purposes of illustration and description. They are not intended to be exhaustive or to limit the invention to the precise forms disclosed. Many variations and modifications of the examples described herein will be apparent to one of ordinary skill in the art in light of the above disclosure. The scope of the invention is to be defined by the claims appended hereto and their equivalents.

Further, in describing representative examples of the invention, the specification may have presented coding methods or processes consistent with the invention as a particular sequence of steps. However, to the extent that a method or process does not rely on the particular order of steps set forth herein, the method or process should not be limited to the particular sequence of steps described. As one of ordinary skill in the art would appreciate, other sequences of steps may be possible. Therefore, the particular order of the steps set forth in the specification should not be construed as limitations on the claims. In addition the claims directed to the method of the invention should not be limited to the performance of their steps in the order written, and one skilled in the art can readily appreciate that the sequences may be varied and still remain within the spirit and scope of the invention.

We claim:

1. A video coding method comprising:
receiving a set of video data for transmission;
identifying at least two partitions from the video data, a first partition containing at least a portion of decoding information enabling a decoding of the video data, a second partition containing at least a portion of information indicative of video content;
encoding at least a portion of the first partition at an application layer of a system to generate partition protection information, the partition protection information allowing a recovery of first partition data when an error occurs to the first partition data; and
transmitting the first partition, the partition protection information, and the second partition.

2. The method of claim 1, wherein a protected bitstream comprising the first partition, the partition protection information, and the second partition is in a syntax of the video data.

3. The method of claim 1, wherein transmitting the first partition, the partition protection information, and the second partition comprises transmitting the first partition, the partition protection information, and the second partition in a syntax of the video data.

4. The method of claim 1, wherein the partition protection information comprises an application-layer error correction code.

5. The method of claim 1, wherein encoding the portion of the first partition comprises generating an error correction code for header information of the video data.

6. The method of claim 1, wherein encoding the portion of the first partition comprises applying Hamming Code as an error correction code.

7. The method of claim 1, wherein the video data comprises a video bitstream and transmitting the first partition, the partition protection information, and the second partition comprises transmitting the first partition, the partition protection information, and the second partition in one video bitstream.

8. The method of claim 1, wherein the error occurs to the first partition data after a transmission of the first partition data.

9. A system comprising:
an input interface to receive a set of video data for transmission;
a data processing device to identify at least two partitions from the video data, a first partition containing at least a portion of decoding information enabling a decoding of the video data, a second partition containing at least a portion of information indicative of video content;
an encoding device being capable of encoding at least a portion of the first partition at an application layer of the system to generate partition protection information, the partition protection information allowing a recovery of first partition data when an error occurs to the first partition data; and
a transmission interface to transmit the first partition, the partition protection information, and the second partition.

10. The system of claim 9, wherein a protected bitstream comprising the first partition, the partition protection information, and the second partition is in a syntax of the video data.

11. The system of claim 9, wherein the transmission interface transmits the first partition, the partition protection information, and the second partition in a syntax of the video data.

12. The system of claim 9, wherein the partition protection information comprises an application-layer error correction code.

13. The system of claim 9, wherein the encoding device encodes the portion of the first partition by generating an error correction code for header information of the video data.

14. The system of claim 9, wherein the encoding device encodes the portion of the first partition comprises by applying Hamming Code as an error correction code.

15. The system of claim 9, wherein the video data comprises a video bitstream and the transmission interface transmits the first partition, the partition protection information, and the second partition in one video bitstream.

16. The system of claim 9, wherein the error occurs to the first partition data after the transmission interface transmits the first partition data.

17. A computing system comprising:
a memory to store instructions; and
a processor configured to process the instructions to perform steps comprising:
receiving a set of data for transmission;
identifying at least two partitions from the data, a first partition containing at least a portion of decoding information enabling a decoding of the data, a second partition containing at least a portion of information indicative of data content;
encoding at least a portion of the first partition at an application layer of the system to generate partition protection information, the partition protection information allowing a recovery of first partition data when an error occurs to the first partition data; and
transmitting the first partition, the partition protection information, and the second partition.

18. The system of claim 17, wherein a protected bitstream comprising the first partition, the partition protection information, and the second partition is in a syntax of the data received for transmission.

19. The system of claim 17, wherein transmitting the first partition, the partition protection information, and the second partition comprises transmitting the first partition, the partition protection information, and the second partition in a syntax of the data received for transmission.

20. The system of claim 17, wherein the partition protection information comprises an application-layer error correction code.
